(19) United States
(12) Patent Application Publication
(10) Pub. No.: US 2015/0166728 A1
(43) Pub. Date: Jun. 18, 2015

(54) CURABLE RESIN, SEALING MEMBER, AND ELECTRONIC DEVICE PRODUCT USING SEALING MEMBER

(71) Applicant: DENSO CORPORATION, Kariya-city (JP)

(72) Inventors: Hiroyuki OKUHIRA, Kariya-city (JP); Akira TAKAKURA, Nagoya-city (JP); Katsuhiro KANIE, Tokai-city (JP)

(21) Appl. No.: 14/564,704

(22) Filed: Dec. 9, 2014

(30) Foreign Application Priority Data
Dec. 13, 2013 (JP) 2013-257548

(51) Int. Cl. C08G 73/10; H01L 23/29; C09D 163/00; C09D 179/08; C08G 59/50; C08G 59/62

(52) U.S. Cl. CPC C08G 73/10; C08G 59/5033; C08G 59/621; C09D 163/00; C09D 179/08; H01L 23/293

(57) ABSTRACT

A curable resin composition includes a main agent, an amine-based curing agent, and a phenol-based curing agent. The main agent includes at least one of a maleimide compound and an epoxy compound. The amine-based curing agent is made of aromatic polyamine. The phenol-based curing agent is made of phenols that has a phenolic OH equivalent of equal to or less than 90 and has a softening point or a melting point of equal to or lower than 100° C.

### CROSS REFERENCE TO RELATED APPLICATIONS

The present application is based on and claims priority to Japanese Patent Application No. 2013-257548 filed on Dec. 13, 2013, the contents of which are incorporated in their entirety herein by reference.

### TECHNICAL FIELD

The present disclosure relates to a curable resin composition, an encapsulant made of a cured product of the curable resin composition, and an electronic device product using the encapsulant.

### BACKGROUND

In an electronic device product, an encapsulant is used for protecting an electronic component such as a semiconductor element from an external environment such as an impact, a pressure, a humidity, and a heat. As the encapsulant, an epoxy/phenol-based encapsulant, in which a main agent is an epoxy resin and a curing agent is a phenol resin, is widely used.

Recently, a semiconductor substrate in an electronic device product is shifted from a Si substrate to a SiC substrate having a higher performance. Although the electronic device product using the SiC substrate is assumed to be used in a high temperature environment of 200 through 250° C., a heat resistant temperature of the epoxy/phenol-based encapsulant is about 150 through 200° C. Thus, a development of an encapsulant having a higher heat resistance is required

Conventionally, as a material having a higher heat resistance, a heat resistant resin composition including a maleimide compound and polyamine has been developed (see JP-A-S63-68637). A cured product of the maleimide resin-based heat-resistant resin composition has a fine heat resistance.

However, while having a fine heat resistance, the cured product of the maleimide resin-based heat-resistant resin composition has a lower toughness and is more fragile compared with the conventional epoxy/phenol-based encapsulant. For example, the toughness of the heat-resistant resin composition including the maleimide compound and polyamine can be increased by adding a softening material used in the epoxy/phenol-based encapsulant. However, in this case, the heat resistance is reduced. Thus, as an encapsulant for a power device used in a high temperature environment, a development of a new material having a fine heat resistance and a fine toughness is desired.

In addition, a resin composition needs to have a compatibility of compounds. However, in curable resin compositions including main agents and curing agents, bad combinations of main agents and curing agents exist. Thus, a material also having a fine compatibility of a main agent and a curing agent is required.

### SUMMARY

It is an object of the present disclosure to provide a curable resin composition having a fine compatibility of a main agent and a curing agent and providing a cured product having a high heat resistance and a high toughness. Other objects of the present disclosure are to provide an encapsulant using the cured product of the curable resin composition, and to provide an electronic device product using the encapsulant.

A curable resin composition according to a first aspect of the present disclosure includes a main agent, an amine-based curing agent, and a phenol-based curing agent. The main agent includes at least one of a maleimide compound and an epoxy compound. The amine-based curing agent is made of aromatic polyamine. The phenol-based curing agent is made of phenols that has a phenolic OH equivalent of equal to or less than 90 and has a softening point or a melting point of equal to or lower than 100° C.

A cured product of the curable resin composition can have a fine heat resistance and a fine toughness.

An encapsulant according to a second aspect of the present disclosure is made of the cured product of the curable resin composition according to the first aspect. The encapsulant can have a high heat resistance and a high toughness. Thus, the encapsulant can be suitable used as an encapsulant, for example, for an electronic device using a SiC substrate.

An electronic device product according to a third aspect of the present disclosure uses the encapsulant according to the second aspect. Even when the electronic device using the encapsulant is in a high temperature environment over 200° C., the encapsulant can sufficiently function. Thus, the electronic device component can have a high reliability at a high temperature.

### BRIEF DESCRIPTION OF THE DRAWINGS

Additional objects and advantages of the present disclosure will be more readily apparent from the following detailed description when taken together with the accompanying drawings. In the drawings:

FIG. 1 is a graph showing a result of a thermal analysis data of a curing agent made of phenylene oxide skeleton diamine (n=3) in an example 1;

FIG. 2 is a graph showing a nuclear magnetic resonance (NMR) spectrum of a curing agent made of phenylene oxide skeleton diamine (n=3) in an example 2; and

FIG. 3 is a diagram showing a cross-sectional view of an electronic device product according to an example 14.

### DETAILED DESCRIPTION

The following describes a curable resin composition according to an embodiment of the present disclosure. The curable resin composition includes a main agent and a curing agent. In the present disclosure, the curing agent is the general term of amine-based curing agents and phenol-based curing agents. Like a general relationship between a general main agent and a curing agent, the main agent includes at least two functional groups in one molecule. In other words, the main agent including at least one of a maleimide compound and an epoxy compound includes two or more functional groups as the sum of epoxy groups and maleimide groups. The maleimide compound and the epoxy compound are prepolymers that are polymerized by reaction with the curing agent, and are, for example, monomers.

A combination ratio of the main agent and the curing agent can be optionally adjusted based on an equivalent ratio of functional groups of the main agent and the curing agent so as to be the general relationship between the main agent and the curing agent. Specifically, the combination ratio can be adjusted so that the equivalent ratio of the functional groups of the main agent and the curing agent is, for example, within a range from 0.5 to 1.5, preferably within a range from 0.8 to 1.2, and more preferably within a range from 0.9 to 1.1.

In the curable resin composition, a ratio of the sum of the number of the functional groups in the main agent (i.e., the sum of the number N_{M} of maleimide groups and the number N_{E} of epoxy groups) and the sum of the number of the functional groups in the curing agent (i.e., the sum of the number N_{A} of amino groups and the number N_{H} of hydroxyl groups), that is, (N_{M}+N_{E})/(N_{A}+N_{H}) is preferably within a range from 0.9 to 1.1. The ratio of the sum of the number of the functional groups in the main agent and the sum of the number of the functional groups in the curing agent (N_{M}+N_{E})/(N_{A}+N_{H}), that is, the equivalent ratio of the main agent and the curing agent is most preferably 1.

The maleimide compound preferably includes two or more maleimide groups in a molecule. In this case, cross-linking is possible without using other main agent.

As the maleimide compound, a bifunctional bismaleimide compound such as 4,4-diphenyl methane bismaleimide, m-phenylene bismaleimide, bisphenol A diphenyl ether bismaleimide, 3,3-dimethyl-5,5-diphenyl methane bismaleimide, 4-methyl-1,3-phenylene bismaleimide, 1,6-bismaleimide-(2,2,4-trimethyl) hexane can be used. A polyfunctional maleimide compound, such as phenyl methane maleimide, can also be used. The number of maleimide groups in the maleimide compound is preferably within a range from 2 to 5.

Preferably, the maleimide compound that includes the bismaleimide compound having two maleimide groups is used. More preferably, the maleimide compound whose main component is the bismaleimide compound is used. In this case, a softening temperature of the maleimide compound is relatively low. Thus, a compatibility of the main agent and the curing agent can be improved.

The epoxy compound preferably includes two or more epoxy groups in a molecule. In this case, curing is possible without using other main agent. In the following listing, “epoxy resin” is a general term of a compound having two or more epoxy groups in a molecule. As the epoxy compound, for example, bisphenolic epoxy resin, aromatic polyfunctional epoxy resin, phenolic polyfunctional epoxy resin, naphthalene type epoxy resin, or epoxy resin having alicyclic skeleton hydrogenated with a benzene ring of the above-described resin can be used. As the bisphenolic epoxy resin, a bisphenol A type and a bisphenol F type are given as examples. As the aromatic polyfunctional epoxy resin, a glycidyl amine type is given as an example. As the phenolic polyfunctional epoxy resin, a phenol novolac type and a cresol novolac type are given as examples. As the naphthalene type epoxy resin, a bifunctional epoxy resin such as EPICLON HP-4032D manufactured by DIC Corporation, and a tetrafunctional epoxy resin such as EPICLON HP-4700 manufactured by DIC Corporation are given as examples. In addition, as the epoxy compound, an epoxy resin having an aliphatic skeleton such as trimethylolpropane and ethylene glycol can also be used.

In the above-described epoxy compound, it is preferable to use an epoxy resin having an aromatic ring such as the bisphenol A type, the glycidyl amine type, the phenol novolac type, the cresol novolac type, and the naphthalene type. In this case, a mechanical property and a glass transition point of the cured product of the curable resin composition can be more improved. In view of further improving the mechanical property and the glass transition point of the cured product, the cresol novolac type and the naphthalene type epoxy resin are preferable as the epoxy compound. In view of further improving the mechanical property and the glass transition point of the cured product, the naphthalene type epoxy resin is specifically preferable as the epoxy compound.

The main agent preferably includes at least the maleimide compound. In this case, a heat resistance of the cured product of the curable resin composition can be more improved. Thus, the curable resin composition is suitably used as an encapsulant used in a high temperature environment. When the maleimide compound and the epoxy compound are used in combination, a content of the epoxy compound is preferably equal to or less than 30 parts by mass (hereafter, referred to as “pts. mass”) with respect to 100 pts. mass of the total content of the maleimide compound and the epoxy compound.

The curable resin composition includes aromatic polyamine as the amine-based curing agent. The aromatic polyamine is an aromatic compound having two or more amino groups. As the aromatic polyamine, for example, aromatic diamine such as diaminodiphenyl sulfone (DDS) and diaminodiphenylmethane (DDM) can be used. As the aromatic polyamine, polyamine having a phenylene oxide skeleton, and polyamine having a phenylene sulfide skeleton can also be used.

The curable resin composition preferably includes at least a diamine compound expressed by the general formula (1) as the amine-based curing agent. In this case, the toughness of the cured product of the curable resin composition can be more improved. This is because of a strong interaction between maleimide parts, between epoxy parts, or between a maleimide part and an epoxy part, and a strong interaction generated by arranging main skeletons of the diamine compound on a plane.

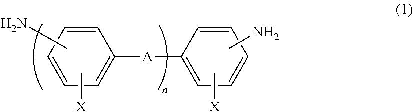

In the general formula (1), A is an oxygen atom or a sulfur atom, X is a hydrogen atom, an alkyl group or an aryl group having a carbon number of equal to or less than 6, and n is a natural number selected from 1 to 10.

In the general formula (1), the amino group and X may be bonded to any positions of benzene rings. In other words, the amino group and X may be bonded to any positions of alt-positions, meta-positions, and para-positions. As the amine-based curing agent, one or more kinds of compounds expressed by the general formula (1) can be used.

The benzene skeletons in the general formula (1) are preferably bonded through the A-atom at meta-positions or para-positions. In this case, the toughness of the cured product of the curable resin composition can be more improved. This is because a steric hindrance in a resin structure becomes smaller, and the benzene rings likely to be arranged on a plane. More preferably, the benzene skeletons in the general formula (1) are bonded through the A-atom at para-positions. In addition, the amino group in the general formula (1) is preferably bonded to the A-atom at a para-position.

X in the general formula (1) is preferably hydrogen or a methyl group, and is most preferably hydrogen. Also in this case, the toughness of the cured product of the curable resin composition can be more improved. It can be considered that this is because a steric hindrance in the resin structure becomes smaller, resin skeletons easily approach to each other, and an interaction between skeletons of the amine-based curing agent, and an interaction between the skeletons of the amine-based curing agent and the skeletons of the main agent are effectively work.

When n in the general formula (1) is too large, not only a synthesis of the diamine compound becomes difficult, but also the melting point of the diamine compound becomes higher. Thus, n in the general formula (1) is preferably within a range from 1 to 10, more preferably within a range from 1 to 5, and further preferably within a range from 1 to 3. As the compound expressed by the general formula (1), one kind of compound selected from compounds in which n is within a range from 1 to 10 can be used. In addition, a mixture of two or more kids of compounds having different n values can also be used. In view of improving the heat resistance and the toughness, it is further more preferable to use the compound of n=3.

In addition, A in the general formula (1) is preferably an oxygen atom. In this case, an adhesiveness of the curable resin composition can be increased. Thus, the curable resin composition is more suitable for an encapsulant. In a case where A in the general formula (1) is a sulfur atom, the heat resistance and the toughness of the cured product of the curable resin composition tend to be improved.

The curable resin composition further includes a phenol-based curing agent made of phenols that has a phenolic OH equivalent of equal to or less than 90 and has a softening point or a melting point of equal to or lower than 100° C. In a case where the phenolic OH equivalent is greater 90, the heat resistance of the cured product of the curable resin composition decreases. Thus, the phenolic OH equivalent is preferably equal to or less than 90, more preferably equal to or less than 70, and further preferably equal to or less than 60. The phenolic OH equivalent is an equivalent of hydroxyl group bonded with the benzene rings.

In a case where a marketed product is used as the phenol-based curing agent, the phenolic OH equivalent is indicated by a manufacturer. The phenolic OH equivalent can also be measured as follows. Specifically, the phenol-based curing agent is added in a mixed solution of pyridine and acetic anhydride. Then, an acetylated product generated from the phenol-based curing agent is back titrated to measure the phenolic OH equivalent.

Phenols having a phenolic OH equivalent greater than 90 is compatible with the main agent even if a softening point or a melting point is higher than 100° C. However, a compatibility of phenols having phenolic OH equivalent equal to or less than 90 is reduced if the softening point or the melting point is greater 100° C. because a hydrogen bond between molecules is strong. As a result, a manufacture of the curable resin composition made of a mixture of the main agent and the curing agent becomes difficult. Thus, the softening point or the melting point of phenols having the phenolic OH equivalent equal to or less than 90 is preferably equal to or less than 100° C., and more preferably equal to or less than 90° C. The softening point or the melting point of phenols can be adjusted by adjusting a skeleton structure of phenols or using a mixture of phenols. The softening point can be obtained, for example, by a ring and ball method.

A combination ratio of the amine-based curing agent and the phenol-based curing agent in the curable resin composition is a matter of design choice. The toughness of the cured product of the curable resin composition tends to increase with increase of the combination ratio of the amine-based curing agent. The heat resistance of the cured product of the curable resin composition tends to increase with increase of the combination ratio of the phenol-based curing agent. Thus, the combination ratio of the amine-based curing agent and the phenol-based curing agent can be optionally adjusted based on an application of the curable resin composition. From the view point of improving the toughness and the heat resistance of the cured product at higher levels, the content of the phenol-base curing agent is preferably within a range from 5 to 85 mass % with respect to the total amount of the amine-based curing agent and the phenol-base curing agent.

The phenol-based curing agent preferably has a hydroxyl skeleton. In this case, the toughness can be improved while restricting a deterioration in heat resistance of the cured product. As a result, the toughness and the heat resistance of the cured product can be improved at higher levels.

The curable resin composition preferably includes a curing catalyst. In this case, the curing of the curable resin composition can be promoted. As the curing catalyst, a commercially available curing catalyst used for a curing reaction of at least one of a maleimide resin and an epoxy resin can be used. As the curing agent, for example, a phosphorus-based catalyst or an amine-based catalyst can be used. More specifically, as the phosphorus-based catalyst, for example, triphenylphosphine or a salt of triphenylphosphine can be used. As the amine-based catalyst, for example, alkylimidazole, CN-containing imidazole, or carboxylate of alkylimidazole or CN-containing imidazole can be used. In addition, as the amine-based catalyst, triazine-modified imidazoles, isocyanuric acid adduct of triazine-modified imidazoles, or hydroxyl group-containing imidazoles can also be used.

As the alkylimidazole, for example, 2-methyl imidazole, 2-phenyl imidazole are given as examples. As the CN-containing imidazole, for example, 1-cyanoethyl-2-methyl imidazole is given as an example. As the triazine-modified imidazoles, for example, 2,4-diamino-6-[2′-methyl imidazolyl-(1′)]-ethyl-s-triazine is given as an example. As the hydroxyl group-containing imidazoles, for example, 2-phenyl-4,5-dihydroxymethyl imidazole is given as an example. As the amine-based catalyst, 2,3-dihydro-1-H-pyrrolo[1,2-a]benzimidazole, 1-dodecyl-2-methyl-3-benzimidazolium chloride, 2-methyl imidazoline, and 2-phenyl imidazoline can also be used. In the above-described catalysts, the curing catalyst is preferably imidazoles. In this case, the curing speed of the curable resin composition can be improved.

In order to adjust a linear expansion coefficient of the cured product, the curable resin composition can include a filler made of, for example, silica or a alumina. In this case, the curable resin composition is more suitably used for an encapsulant of an electronic device product. The optimum content of the filler depends on the application of the curable resin composition. For example, when the curable resin composition is used for a power device product, the content of the filler with respect to the total amount of the curable resin composition is preferably within a range from 60 to 95 mass %, more preferably within a range from 65 to 90 mass %, and further preferably within a range from 70 to 85 mass %. Specifically, the content of the filler can be suitably adjusted so as to obtain a desired linear expansion coefficient.

The curable resin composition may be added with an adhesion assistant. In this case, the curable resin composition is more suitably used as an encapsulant. As the adhesion assistant, for example, a silane compound can be used. As the silane compound, for example, glycidoxypropyltrimethoxysilane and aminopropyltrimethoxysilane are given as examples.

Next, an encapsulant and an electronic device product according to embodiments of the present disclosure will be described. The encapsulant is made of the cured product of the curable resin composition and is suitably used for an electronic device product. Especially, the encapsulant is suitably used for a power device using a SiC substrate. In this case, the fine heat resistance and the fine toughness of the cured product of the curable resin composition can be sufficiently utilized. In particular, a power device using a SiC substrate may be exposed to a high temperature environment over 240° C. Thus, in this case, the fine heat resistance of the cured product of the curable resin composition can be utilized.

As the electronic device product, a semiconductor module (a power card) used for a power control unit (PCU) of a vehicle, in particular, a hybrid vehicle is given as an example. As an encapsulant sealing a power device (a power control semiconductor element) in the semiconductor module, the cured product of the above-described curable resin composition can be used.

### Example 1

Next, a curable resin composition of an example 1 will be described. In the present example, a curable resin composition including a main agent and a curing agent is manufactured. The curable resin composition includes a maleimide compound as the main agent. In addition, the curable resin composition includes a predetermined diamine compound as an amine-based curing agent, and includes a predetermined phenols as a phenol-based curing agent.

Firstly, as the amine-based curing agent, a diamine compound expressed by the following general formula (2) is synthesized. Hereafter, the diamine compound expressed by the following general formula (2) is referred to as a first amine-based curing agent.

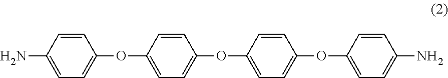

Specifically, firstly, 4,4′-dihydroxydiphenyl ether and p-chloronitrobenzene are mixed to N,N-dimethylacetamide as a reaction solvent at a ratio of OH:Cl=1:1.1 in equivalent ratio. After the temperature of reaction solvent is increased to 80° C., potassium carbonate is added to the reaction solvent at a ratio of OH:potassium carbonate=1:1.1 in equivalent ratio with 4,4′-dihydroxydiphenyl ether.

Next, the reaction solvent is heated at a temperature of 125° C. for 5 hours so as to be reacted. Then, the reaction solvent is poured into ion exchanged water to reprecipitation, and a solid body is obtained by filtration. Furthermore, after the solid body is cleaned with hot methanol, a solid body is obtained by filtration. The obtained solid body is dried to obtain phenylene ether oligomer (n=3) having nitro groups on both terminals. The yield of phenylene ether oligomer is 90%.

Next, as a reaction solvent, a mixed solvent of isopropyl alcohol and tetrahydrofuran is prepared. Then, phenylene ether oligomer having nitro groups on both terminals and prepared as described above and palladium carbon are added to the reaction solvent. A combination ratio of phenylene ether oligomer and palladium carbon is 1:0.05 in mass ratio.

After the temperature of the reaction solvent is increased to 55° C., hydrated hydrazine is added to the reaction solvent for 1 hour. The adding amount of hydrated hydrazine is adjusted to such a ratio that an equivalent ratio of the nitro groups in phenylene ether oligomer and hydrated hydrazine is 1:4. Next, the reaction solvent is heated at a temperature of 60° C. for 5 hours to be reacted. Accordingly, the nitro groups on the terminals of phenylene ether oligomer is reduced to amino groups. After palladium carbon is removed from the reaction solvent by hot filtration, a vacuum filtration is performed, and the solvent of ⅔ quantity (volume) of a prepared quantity is distillated. Next, isopropyl alcohol of the same quantity (volume) as the distillated solvent is newly added, and the temperature is increased to 80° C. After that, a solid body is deposited by cooling.

Next, after a solid body is obtained by filtration, the solid body is dried. Accordingly, phenylene ether oligomer (n=3) having amino groups on both terminals, that is, the diamine compound (a first amine-based curing agent) expressed by the general formula (2) is obtained. The yield of the diamine compound is 85%. The obtained diamine compound is subjected to a differential scanning calorimeter (DSC) analysis using a differential scanning calorimeter named “EXSTRA 6000” manufactured by SII Nano Technology Inc. The measurement conditions and the results of the DSC analysis is as follows.

[Temperature Program]
Heating Rate: 10.00° C./min
Hold Temperature: 300° C.
Hold Time: 0 min

[Valve Program]
V1 Initial State: 0
V2 Initial State: 0

[PID Program]
P Initial Value: 10
I Initial Value: 10
D Initial Value: 10

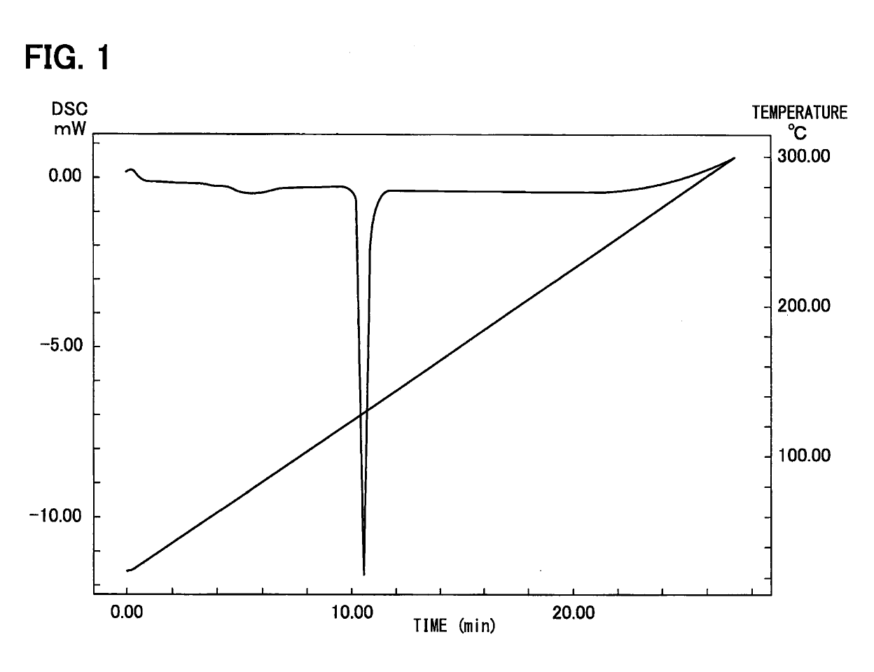

FIG. 1 shows a relationship between a DSC curve and a time, and a relationship between a temperature and a time in the DSC analysis. In FIG. 1, a left vertical axis indicates a heat flow rate (mW), a horizontal axis indicates a time (min), and a right vertical axis indicates a temperature (° C.). An analysis result of the DSC curve is as follows.
Start Point: 116.70° C.
End Point: 146.59° C.
Peak: 128.81° C.
On Set: 125.12° C.
End Set: 130.98° C.
−264.29 mJ
−105.72 J/g
−63.14 mcal
Peak Height: −11.23 mW

From the result, a sharp peak indicating a melting point of the obtained diamine compound is confirmed in the vicinity of a temperature of 129° C. Although it is not shown, a structure of the diamine compound is confirmed by a nuclear magnetic resonance (NMR) measurement, and a purity of the obtained compound is confirmed by a high performance liquid chromatography (HPLC).

Next, the curable resin composition is manufactured. Firstly, as the maleimide compound, phenylmethane-type bismaleimide (“BMI-2300” manufactured by Daiwa Kasei Industry Co., Ltd. and having a maleimide equivalent of 179) is prepared. As the amine-based curing agent, the above-described diamine compound expressed by the general formula (2) is prepared. As the phenol-based curing agent, “EPICLON EXB-9560” manufactured by DIC Corporation and being phenols having hydroquinone skeleton is prepared. Hereafter, this phenol-based curing agent is referred to as a first phenol-based curing agent. The first phenol-based curing agent has a phenolic OH equivalent of 57 and has a melting point of 88° C. As an adhesion assistant, glycidoxypropyltrimethoxysilane is prepared. In addition, as a curing catalyst, 2-phenylimidazole named “2PZ” manufactured by Shikoku Chemicals Corporation is prepared. Furthermore, as a filler (spherical silica), “RD-8” manufactured by Tatsumori Ltd. is prepared. The maleimide compound, the diamine compound, the phenols, the adhesion assistant, and the filler are put into an open roll kneading machine manufactured by Toyo Seiki Kogyo Co., Ltd. and heated at 120° C., and are mixed for 5 min. A combination ratio of materials are shown in Table 1 described later. By the above-described way, the curable resin composition of the example 1 is obtained.

### Examples 2-13 and Comparative Examples 1-5

Next, curable resin compositions in which kinds and combination ratios of a main agent, an amine-based curing agent, and a phenol-based agent are different from those in the example 1 are manufactured. In the manufacture of the curable resin compositions of the examples and the comparative examples, three kinds of amine-based curing agents (second through fourth amine-based curing agents) are used other than the first amine-based curing agent being the diamine compound expressed by the general formula (2). Firstly, the second through fourth amine-based curing agents will be described.

The second amine-based curing agent is a diamine compound expressed by the following general formula (3).

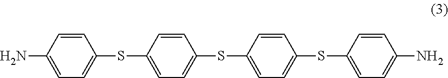

The diamine compound (the second amine-based curing agent) expressed by the general formula (3) is synthesized as described below. Specifically, firstly, dithiophenylene sulfide and p-chloronitrobenzene are mixed to N,N-dimethylacetamide as a reaction solvent at such a ratio that an equivalent ratio of SH groups and Cl groups is SH:Cl=1:1.1. After the temperature of reaction solvent is increased to 60° C., potassium carbonate is added to the reaction solvent at such a ratio that an equivalent ratio with SH groups in dithiophenylene sulfide is SH:potassium carbonate=1:1.1.

Next, the reaction solvent is heated at a temperature of 120° C. for 5 hours so as to be reacted. Then, the reaction solvent is poured into ion exchanged water to reprecipitation, and a solid body is obtained by filtration. Furthermore, after the solid body is cleaned with hot ethanol, a solid body is dried. Accordingly, phenylene sulfide oligomer (n=3) having nitro groups on both terminals is obtained. The yield of phenylene sulfide oligomer is 80%.

Then, phenylene sulfide oligomer having nitro groups on both terminals and prepared as described above and palladium carbon are added to isopropyl alcohol as a reaction solvent. A combination ratio of phenylene sulfide oligomer and palladium carbon is 1:0.05 in mass ratio.

After the temperature of the reaction solvent is increased to 70° C., hydrated hydrazine is added to the reaction solvent for 1 hour. The adding amount of hydrated hydrazine is adjusted to such a ratio that an equivalent ratio of the nitro groups in phenylene sulfide oligomer and hydrated hydrazine is 1:4. Next, the reaction solvent is heated at a temperature of 80° C. for 5 hours to be reacted. Accordingly, the nitro groups on the terminals of phenylene sulfide oligomer is reduced to amino groups. After palladium carbon is removed from the reaction solvent by hot filtration, a solid body is deposited by cooling.

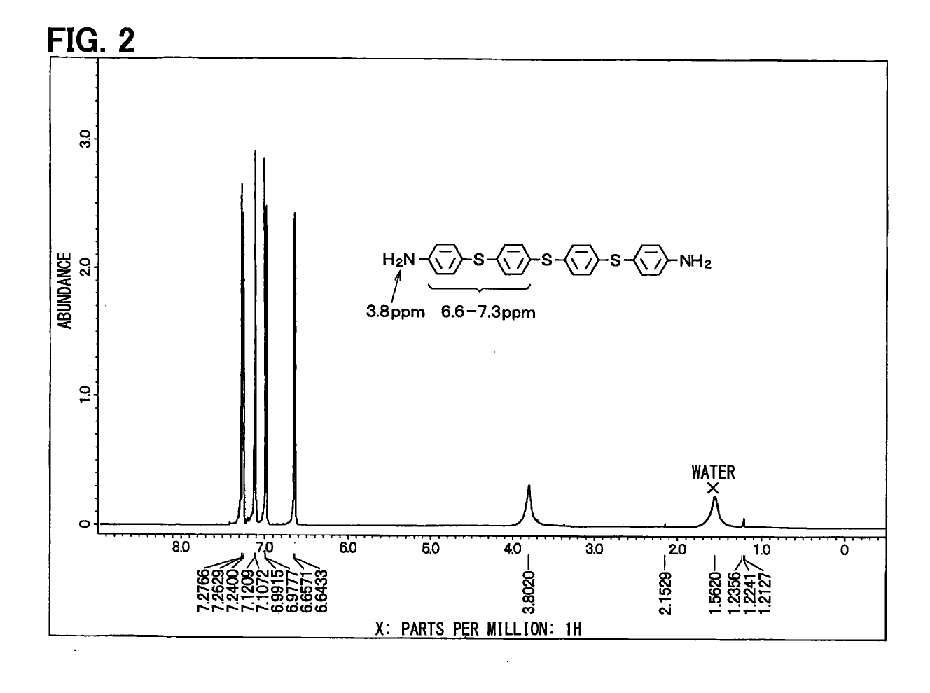

Next, after a solid body is obtained by filtration, the solid body is dried. Accordingly, phenylene sulfide oligomer (n=3) having amino groups on both terminals, that is, the diamine compound (the second amine-based curing agent) expressed by the general formula (3) is obtained. The yield of the diamine compound is 75%. A structure of the obtained diamine compound is confirmed by an NMR measurement. For reference, an NMR spectrum of the phenylene sulfide oligomer (n=3) expressed by the general formula (3) by is shown in FIG. 2.

The third amine-based curing agent is a diamine compound expressed by the following general formula (4). As the third amine-based curing agent, “TPE-R” manufactured by Wakayama Seika Kogyo Co., Ltd. is used.

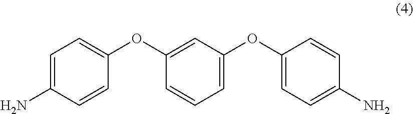

The fourth amine-based curing agent is diaminodiphenylsulfone (DDS). As the fourth amine-based curing agent, “Aradur 9664-1” manufactured by Huntsman Corporation is used.

In addition, in the manufacture of the curable resin compositions of the examples and the comparative examples, three kinds of phenol-based curing agents (second through fourth phenol-based curing agents) are used other than the first phenol-based curing agent used in the example 1.

The second phenol-based curing agent is phenols having a phenolic OH equivalent of 80 and having a softening point of 92° C. As the second phenol-based curing agent, “EPICLON EXB-9600” manufactured by DIC Corporation is used. The third phenol-based curing agent is phenols having a phenolic OH equivalent of 104 and having a softening point of 80° C. As the third phenol-based curing agent, “EPICLON TD-2131” manufactured by DIC Corporation is used. The fourth phenol-based curing agent is phenols having a phenolic OH equivalent of 80 and has a melting point of 223° C. As the fourth phenol-based curing agent, “bisphenol fluorene” manufactured by Osaka Gas Chemicals Co., Ltd. is used.

In the example 9 and the comparative example 5, the epoxy compound is used with the maleimide compound as the main agent. In the examples 11-13 and the comparative example 5, the epoxy compound is used as the main agent. In the examples and the comparative examples, as the epoxy compound, a naphthalene type epoxy compound named “HP-4710” manufactured by DIC Corporation is used.

The main agent, the amine-based curing agent, the phenol-based curing agent, the adhesion assistant, the curing catalyst, and the filler are combined at combination ratios shown in Table 1 and Table 2 and the curable resin compositions are manufactured in a manner similar to the example 1. The adhesion assistant, the curing catalyst, and the filler are same as those in the example 1.

Next, compatibilities of the curable resin compositions of the examples 1-13 and the comparative examples 1-5 are evaluated. Specifically, the compatibility of the main agent and the curing agent is visually evaluated when each of the curable resin compositions is manufactured. A case where the main agent and the curing agent are compatibilized by the kneading at 120° C. for 5 minutes and the composition becomes transparent is evaluated as “good (G)”. A case where the main agent and the curing agent are not compatibilized by the kneading at 120° C. for 5 minutes and the composition remains opaque is evaluated as “no good (NG)”. The results are shown in Table 1 and Table 2.

In addition, heat resistances and toughnesses of the curable resin compositions of the examples 1-13 and the comparative examples 1-5 are evaluated. Specifically, the curable resin compositions are molded by transfer molding and are cured to obtain cured products. The transfer molding is performed under conditions that a mold temperature is 200° C. and a molding time is 5 minutes. Then, cubical specimens (5 mm×5 mm×5 mm) for evaluating the heat resistances and plate-shaped specimens (width 10 mm×length 80 mm×thickness 4 mm) for evaluating the toughnesses are cut out from the cured products.

The evaluation of the heat resistances is performed by measuring glass transition points Tg of the cubical specimens. Specifically, the glass transition points Tg in a process of decreasing the temperature of the cubical specimens from 320° C. to the room temperature (25° C.) are measured. The glass transition points Tg is measured using a thermomechanical analysis (TMA) apparatus named “EXSTAR 6000” manufactured by SII nanotechnology Corporation. The values of the glass transition points Tg of the specimens are shown in Table 1 and Table 2. Furthermore, the heat resistances of the specimens are evaluated based on the glass transition points Tg. Specifically, a case where the glass transition point Tg is equal to or higher than 262.5° C. is evaluated as “very good (VG)”, a case where the glass transition point Tg is lower than 262.5° C. and is equal to or higher than 250° C. is evaluated as “good (G)”, and a case where the glass transition point Tg is lower than 250° C. is evaluated as “no good (NG)”. The evaluation results are shown in Table 1 and Table 2. The evaluation reference temperature 262.5° C. is a temperature higher than 250° C., which is a heat resistance temperature required for an electronic device product using an SiC substrate, by 5° C.

The evaluation of the toughnesses are performed by measuring bending strengths (MPa) and bending strains (%) of the plate-shaped specimens. The bending strengths and the bending strains are measured by three-point bending tests based on JIS K 7171 (2008). The measurement is performed under conditions that a distance between supporting points is 64 mm, a test rate is 2 mm/min, and a measurement temperature is the room temperature (25° C.). The bending strains can be calculated by the following equation.

bending strain (%)=deflection×6×thickness/(distance between supporting points)².

Values of the bending strengths and the bending strains of the specimens are shown in Table 1 and Table 2. In addition, the toughnesses of the specimens are evaluated based on the bending strengths and the bending strains. Specifically, a case where the bending strength is equal to or greater than 140 MPa is evaluated as “VG”, a case where the bending strength is less than 140 MPa and is equal to or greater than 120 MPa is evaluated as “G,” and a case where the bending strength is less than 120 MPa is evaluated as “NG.” In addition, a case where the bending strain is higher than 0.4% is evaluated as “VG”, a case where the bending strain is less than 0.4% and is equal to or higher than 0.3% is evaluated as “G” and a case where the bending strain is less than 0.3% is evaluated as “NG” The results are shown in Table 1 and Table 2.

TABLE 1

| Example No. | | 1 | 2 | 3 | 4 | 5 | 6 | 7 | 8 | 9 | 10 | 11 | 12 | 13 |
|---|---|---|---|---|---|---|---|---|---|---|---|---|---|---|
| Main Agent | Maleimide Compound | 100 | 100 | 100 | 100 | 100 | 100 | 100 | 100 | 70 | 100 | _{—} | _{—} | _{—} |
| (pts. mass) | Epoxy Compound | — | — | — | — | — | — | — | — | 30 | — | 100 | 100 | 100 |
| First Amine-Based Curing Agent | | 48.3 | 42.9 | 26.8 | 10.7 | 5.4 | 26.8 | — | — | 29.1 | — | 34.3 | 34.3 | — |
| (Amine Equivalent: 96) (pts. mass) | | | | | | | | | | | | | | |
| Second Amine-Based Curing Agent | | — | — | — | — | — | — | — | 30.2 | — | — | — | — | 38.6 |
| (Amine Equivalent: 108) (pts. mass) | | | | | | | | | | | | | | |
| Third Amine-based Curing Agent | | — | — | — | — | — | — | 20.4 | — | — | — | — | — | — |
| (Amine Equivalent: 73) (pts. mass) | | | | | | | | | | | | | | |
| Fourth Amine-Based Curing Agent | | — | — | — | — | — | — | — | — | — | 17.3 | — | — | — |
| (Amine Equivalent: 62) (pts. mass) | | | | | | | | | | | | | | |
| First Phenol-Based Curing Agent | | 3.2 | 6.4 | 15.9 | 25.5 | 28.7 | — | 15.9 | 15.9 | 17.3 | — | 20.4 | — | — |
| (OH Equivalent: 57) | | | | | | | | | | | | | | |
| (Softening Point: 88° C.) (pts. mass) | | | | | | | | | | | | | | |
| Second Phenol-Based Curing Agent | | — | — | — | — | — | 22.3 | — | — | — | 22.3 | — | 28.6 | 28.6 |
| (OH Equivalent: 80) | | | | | | | | | | | | | | |
| (Softening Point: 92° C.) (pts. mass) | | | | | | | | | | | | | | |
| Adhesion Assistant (pts. mass) | | 2 | 2 | 2 | 2 | 2 | 2 | 2 | 2 | 2 | 2 | 2 | 2 | 2 |
| Catalyst (pts. mass) | | 1 | 1 | 1 | 1 | 1 | 1 | 1 | 1 | 1 | 1 | 1 | 1 | 1 |
| Filler (mass %) | | 80 | 80 | 80 | 80 | 80 | 80 | 80 | 80 | 80 | 80 | 80 | 80 | 80 |
| Compatibility | | G | G | G | G | G | G | G | G | G | G | G | G | G |
| Heat | Tg (° C.) | 267 | 270 | 289 | 300 | 300 | 300 | 288 | 280 | 268 | 300 | 255 | 266 | 250 |
| Resistance | Evaluation | VG | VG | VG | VG | VG | VG | VG | VG | VG | VG | G | VG | G |
| Mechanical | Bending Strength (Mpa) | 178 | 178 | 176 | 165 | 145 | 145 | 175 | 170 | 164 | 123 | 160 | 163 | 160 |
| Property | Evaluation | VG | VG | VG | VG | VG | VG | VG | VG | VG | G | VG | VG | VG |
| | Bending Strain (%) | 0.6 | 0.59 | 0.5 | 0.48 | 0.38 | 0.44 | 0.5 | 0.53 | 0.45 | 0.3 | 0.3 | 0.38 | 0.4 |
| | Evaluation | VG | VG | VG | VG | VG | VG | VG | VG | VG | G | G | G | VG |

TABLE 2

| Comparative Example No. | | 1 | 2 | 3 | 4 | 5 |
|---|---|---|---|---|---|---|
| Main Agent | Maleimide Compound | 100 | 100 | 100 | — | 70 |
| (pts. mass) | Epoxy Compound | — | — | — | 100 | 30 |
| First Amine-Based Curing Agent | | — | 26.8 | 26.8 | 34.3 | 29.1 |
| (Amine Equivalent: 96) (pts. mass) | | | | | | |
| Second Amine-Based Curing Agent | | — | — | — | — | — |
| (Amine Equivalent: 108) (pts. mass) | | | | | | |
| Third Amine-based Curing Agent | | — | — | — | — | — |
| (Amine Equivalent: 73) (pts. mass) | | | | | | |
| Fourth Amine-Based Curing Agent | | 34.6 | — | — | — | — |
| (Amine Equivalent: 62) (pts. mass) | | | | | | |
| First Phenol-Based Curing Agent | | — | — | — | — | — |
| (OH Equivalent: 57) | | | | | | |
| (Softening Point: 88° C.) (pts. mass) | | | | | | |
| Second Phenol-Based Curing Agent | | — | — | — | — | — |
| (OH Equivalent: 80) | | | | | | |
| (Softening Point: 92° C.) (pts. mass) | | | | | | |
| Third Phenol-Based Curing Agent | | — | 29.1 | — | — | — |
| (OH Equivalent: 104) | | | | | | |
| (Softening Point: 80° C.) (pts. mass) | | | | | | |
| Fourth Phenol-Based Curing Agent | | — | — | 22.3 | 28.6 | 24.2 |
| (OH Equivalent: 80) | | | | | | |
| (Melting Point: 223° C.) (pts. mass) | | | | | | |
| Adhesion Assistant (pts. mass) | | 2 | 2 | 2 | 2 | 2 |
| Catalyst (pts. mass) | | 1 | 1 | 1 | 1 | 1 |
| Filler (mass %) | | 80 | 80 | 80 | 80 | 80 |
| Compatibility | | G | G | NG | NG | NG |
| Heat | Tg (° C.) | 275 | 245 | — | — | — |
| Resistance | Evaluation | VG | NG | — | — | — |
| Mechanical | Bending Strength (Mpa) | 115 | 173 | — | — | — |
| Property | Evaluation | NG | VG | — | — | — |
| | Bending Strain (%) | 0.28 | 0.64 | — | — | — |
| | Evaluation | NG | VG | — | — | — |

As shown in Table 1, the curable resin compositions of the examples 1-13 that include the amine-based curing agent made of aromatic polyamine and the phenol-based curing agent having the phenolic OH equivalent of equal to or less than 90 and having the melting point of equal to or less than 100° C. have fine heat resistances and fine toughnesses. In the curable resin compositions, the main agent may be either the maleimide compound, the epoxy compound, or mixture of the maleimide compound and the epoxy compound. In either case, the curable resin composition has the fine heat resistance and the fine toughness. In addition, in the curable resin compositions of the examples 1-13, the compatibilities of the main agents and the curing agents are also fine.

In contrast, as shown in Table 2, the curable resin composition of the comparative example 1 that does not include the phenol-based curing agent has a low bending strength and a low bending strain and has a problem with toughness. In addition, the curable resin composition of the comparative example 2 that includes the phenol-based curing agent having the phenolic OH equivalent of greater than 90 has a low glass transition point Tg and has a problem with heat resistance. In the curable resin compositions of the comparative examples 3-5 that include the phenol-based curing agents having melting points higher than 100° C., the compatibilities of the main agents and the curing agents are insufficient even when the main agents are made of the maleimide compound, the epoxy compound, or a mixture of the maleimide compound and the epoxy compound.

### Example 14

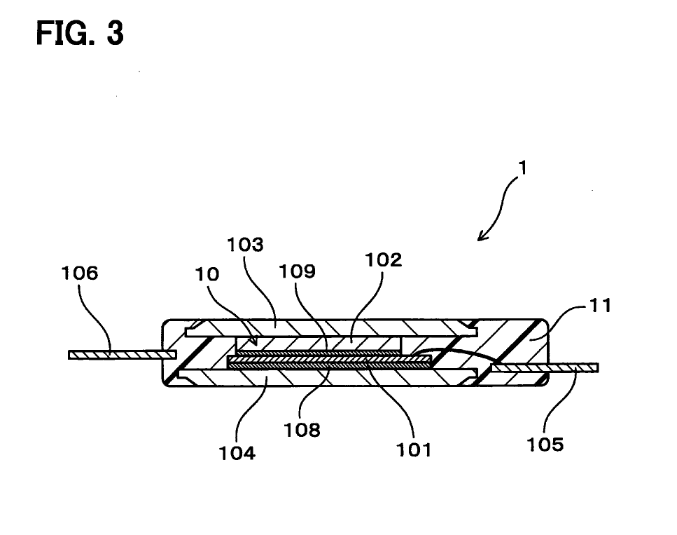

Next, an electronic device, product 1 of an example 14 using the cured product of the curable resin composition of the example 1 as an encapsulant will be described. As shown in FIG. 3, the electronic device product 1 according to the present example is a semiconductor module (a power card) used for a power control unit in a hybrid vehicle. In the electronic device product 1, a power device 101, a copper spacer 102, and heat radiation copper plates 103, 104 are soldered by a reflow method to form an electronic component 10, and the electronic component 10 is sealed with electrode terminals 105, 106 by an encapsulant 11. In FIG. 3, a region between the power device 101 and the copper spacer 102 and a region between the power device 101 and the heat radiation copper plate 104 are joint portions 108, 109 made of solder.

In a manufacturing process of the electronic device product 1, after a primer is applied to the electronic component 10, the electronic component 10 is disposed in a molding tool. Then, the curable resin composition of the example 1 is poured into the molding tool at a temperature of 200° C. and is molded by transfer molding. After that, by holding the molding tool at a temperature of 250° C. for 4 hours, the curable resin composition is cured. Accordingly, the electronic device product 1 using the cured product of the curable resin composition of the example 1 as the encapsulant 11 can be obtained (see FIG. 3).

In the electronic device product 1 of the present example, the cured product of the curable resin composition of the example 1 having the fine heat resistance and the fine toughness is used as the encapsulant 11. Thus, even when the electronic device 1 is used in a high temperature environment about 240° C., the encapsulant 11 can sufficiently exert a sealing function and can have a fine toughness. Thus, the electronic device product 1 has a fine reliability in a high temperature.

In the present example, the curable resin composition of the example 1 is used. However, similar electronic device products can also be manufactured using the curable resin compositions of the examples 2-13. In such cases, the electronic device products utilizing the fine toughnesses and the fine heat resistances (see Table 1) of the curable resin compositions of the examples 2-13 can be obtained.

What is claimed is:

1. A curable resin composition comprising:
a main agent including at least one of a maleimide compound and an epoxy compound;
an amine-based curing agent made of aromatic polyamine; and
a phenol-based curing agent made of phenols that has a phenolic OH equivalent of equal to or less than 90 and has a softening point or a melting point of equal to or lower than 100° C.

2. The curable resin composition according to claim 1, wherein
the amine-based curing agent includes a diamine compound represented by a general formula (1), 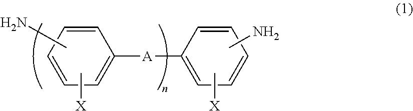
wherein A is an oxygen atom or a sulfur atom, X is a hydrogen atom, an alkyl group or an aryl group having a carbon number of equal to or less than 6, and n is a natural number selected from 1 to 10.

3. The curable resin composition according to claim 2, wherein
benzene skeletons in the general formula (1) are bonded through A at meta-positions or para-positions.

4. The curable resin composition according to claim 2, wherein
X in the general formula (1) is the hydrogen atom.

5. The curable resin composition according to claim 2, wherein
A in the general formula (1) is the oxygen atom.

6. The curable resin composition according to claim 1, wherein
the main agent includes at least the maleimide compound.

7. An encapsulant made of a cured product of the curable resin composition according to claim 1.

8. An electronic device product using the encapsulant according to claim 7.
